(19) United States
(12) Patent Application Publication
(10) Pub. No.: US 2025/0098248 A1
(43) Pub. Date: Mar. 20, 2025

(54) SEMICONDUCTOR DEVICE MANUFACTURING METHOD AND SEMICONDUCTOR MANUFACTURING APPARATUS

(71) Applicant: Kioxia Corporation, Tokyo (JP)

(72) Inventors: Masaya NAKATA, Yokkaichi Mie (JP); Kota TAKAHASHI, Yokkaichi Mie (JP); Yusuke MIKI, Yokkaichi Mie (JP); Takuma DOI, Yokkaichi Mie (JP); Kazuhiro MATSUO, Kuwana Mie (JP); Akifumi GAWASE, Kuwana Mie (JP); Kenichiro TORATANI, Yokkaichi Mie (JP)

(73) Assignee: Kioxia Corporation, Minato-ku, Tokyo (JP)

(21) Appl. No.: 18/828,277

(22) Filed: Sep. 9, 2024

(30) Foreign Application Priority Data
Sep. 19, 2023 (JP) 2023-151647

(51) Int. Cl. H01L 29/26; C23C 16/52; H01J 37/32; H01L 21/02; H01L 21/3213; H01L 29/66

(52) U.S. Cl. CPC H10D 62/80; C23C 16/52; H01J 37/3244; H01L 21/02164; H01L 21/02323; H01L 21/0234; H01L 21/02697; H01L 21/32136; H10D 30/025; H01J 2237/3341; H01J 2237/3355

(57) ABSTRACT

A semiconductor device manufacturing method of embodiments includes: forming a first conductive film containing indium on a substrate; forming a first insulating film; forming a second conductive film; forming a second insulating film; forming an opening penetrating the second insulating film, the second conductive film, and the first insulating film to reach the first conductive film; forming a third insulating film in the opening so as to be in contact with bottom and side surfaces of the opening; removing the third insulating film at a bottom of the opening to expose the first conductive film at the bottom of the opening; performing a first treatment using a first gas containing silicon or a second treatment using a second gas containing oxygen; and forming a semiconductor film in the opening without exposing the substrate to an atmosphere with a pressure equal to or more than atmospheric pressure.

### CROSS-REFERENCE TO RELATED APPLICATION

This application is based upon and claims the benefit of priority from Japanese Patent Application No. 2023-151647, filed on Sep. 19, 2023, the entire contents of which are incorporated herein by reference.

### FIELD

Embodiments described herein relate generally to a semiconductor device manufacturing method and a semiconductor manufacturing apparatus.

### BACKGROUND

An oxide semiconductor transistor in which a channel is formed in an oxide semiconductor layer has an excellent characteristic that the channel leakage current during off operation is very small. For this reason, for example, the oxide semiconductor transistor can be applied as a switching transistor of a memory cell in a dynamic random access memory (DRAM).

### BRIEF DESCRIPTION OF THE DRAWINGS

FIG. 1 is a schematic cross-sectional view of a semiconductor device manufactured by a semiconductor device manufacturing method according to a first embodiment;

FIG. 2 is a schematic cross-sectional view of a semiconductor device manufactured by the semiconductor device manufacturing method according to the first embodiment;

FIG. 3 is a schematic cross-sectional view showing an example of the semiconductor device manufacturing method according to the first embodiment;

FIG. 4 is a schematic cross-sectional view showing an example of the semiconductor device manufacturing method according to the first embodiment;

FIG. 5 is a schematic cross-sectional view showing an example of the semiconductor device manufacturing method according to the first embodiment;

FIG. 6 is a schematic cross-sectional view showing an example of the semiconductor device manufacturing method according to the first embodiment;

FIG. 7 is a schematic cross-sectional view showing an example of the semiconductor device manufacturing method according to the first embodiment;

FIG. 8 is a schematic cross-sectional view showing an example of the semiconductor device manufacturing method according to the first embodiment;

FIG. 9 is a schematic cross-sectional view showing an example of the semiconductor device manufacturing method according to the first embodiment;

FIG. 10 is a schematic cross-sectional view showing an example of the semiconductor device manufacturing method according to the first embodiment;

FIG. 11 is a schematic cross-sectional view showing an example of the semiconductor device manufacturing method according to the first embodiment;

FIG. 12 is a schematic cross-sectional view showing an example of a semiconductor device manufacturing method according to a second embodiment;

FIG. 13 is a schematic cross-sectional view showing an example of the semiconductor device manufacturing method according to the second embodiment;

FIG. 14 is a schematic cross-sectional view showing an example of the semiconductor device manufacturing method according to the second embodiment;

FIG. 15 is a schematic cross-sectional view showing an example of the semiconductor device manufacturing method according to the second embodiment;

FIG. 16 is a schematic cross-sectional view showing an example of the semiconductor device manufacturing method according to the second embodiment;

FIG. 17 is a schematic cross-sectional view showing an example of the semiconductor device manufacturing method according to the second embodiment;

FIG. 18 is a schematic diagram of a semiconductor manufacturing apparatus according to a third embodiment;

FIG. 19 is a schematic diagram of a semiconductor manufacturing apparatus according to a fourth embodiment;

FIG. 20 is a schematic diagram of a semiconductor manufacturing apparatus according to a modification example of the fourth embodiment;

FIG. 21 is a schematic diagram of a semiconductor manufacturing apparatus according to a fifth embodiment; and

FIG. 22 is a schematic diagram of a semiconductor manufacturing apparatus according to a sixth embodiment.

### DETAILED DESCRIPTION

A semiconductor device manufacturing method of embodiments includes: forming a first conductive film containing indium (In) on a substrate; forming a first insulating film on the first conductive film; forming a second conductive film on the first insulating film; forming a second insulating film on the second conductive film; forming an opening penetrating the second insulating film, the second conductive film, and the first insulating film to reach the first conductive film; forming a third insulating film in the opening so as to be in contact with bottom and side surfaces of the opening; removing the third insulating film at a bottom of the opening to expose the first conductive film at the bottom of the opening; performing at least one treatment selected from a group including a first treatment using a first gas containing silicon (Si) and a second treatment using a second gas containing oxygen (O); and forming a semiconductor film in the opening without exposing the substrate to an atmosphere with a pressure equal to or more than atmospheric pressure after the at least one treatment.

Hereinafter, embodiments will be described with reference to the diagrams. In addition, in the following description, the same or similar members and the like are denoted by the same reference numerals, and the description of the members and the like once described may be omitted as appropriate.

In addition, in this specification, the terms “on”, “below”, “upper”, and “lower” may be used for convenience. “on”, “below”, “upper”, and “lower” are terms that only indicate the relative positional relationship in the diagrams, but are not terms that define the positional relationship with respect to gravity.

The qualitative analysis and quantitative analysis of the chemical composition of members forming the semiconductor device in this specification can be performed by, for example, secondary ion mass spectrometry (SIMS), energy dispersive X-ray spectroscopy (EDX), and Rutherford back-scattering spectroscopy (RBS). In addition, when measuring the thickness of each member forming the semiconductor device, a distance between members, crystal grain size, and the like, for example, a transmission electron microscope (TEM) can be used. In addition, for the identification of the constituent materials of members forming the semiconductor device and the measurement of the abundance ratio of the constituent materials, for example, X-ray photoelectron spectroscopy (XPS), hard X-ray photoelectron spectroscopy (HAXPES), and electron energy loss spectroscopy (EELS) can be used.

### First Embodiment

A semiconductor device manufacturing method according to a first embodiment includes: forming a first conductive film containing indium (In) on a substrate; forming a first insulating film on the first conductive film; forming a second conductive film on the first insulating film; forming a second insulating film on the second conductive film; forming an opening penetrating the second insulating film, the second conductive film, and the first insulating film to reach the first conductive film; forming a third insulating film in the opening so as to be in contact with bottom and side surfaces of the opening; removing the third insulating film at a bottom of the opening to expose the first conductive film at the bottom of the opening; performing at least one treatment selected from a group including a first treatment using a first gas containing silicon (Si) and a second treatment using a second gas containing oxygen (O); and forming a semiconductor film in the opening without exposing the substrate to an atmosphere with a pressure equal to or more than atmospheric pressure after the at least one treatment.

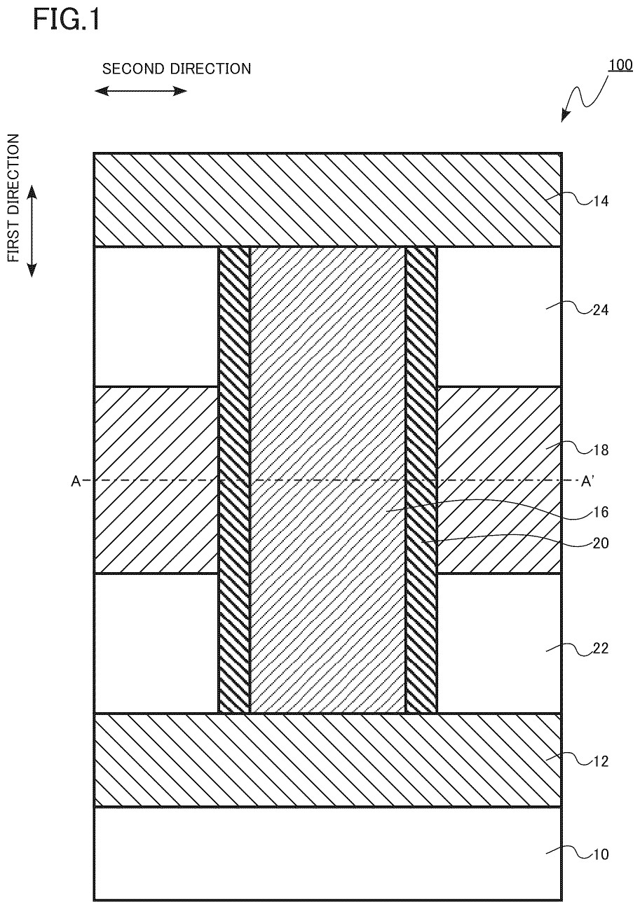

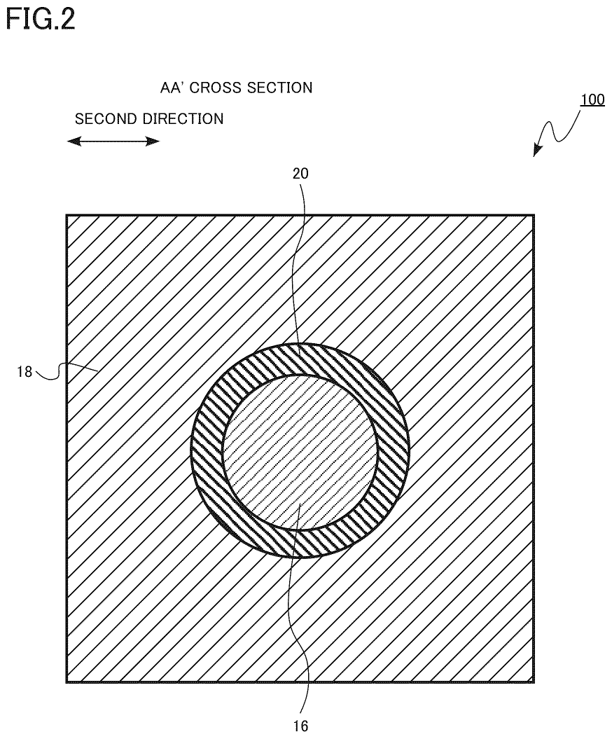

FIGS. 1 and 2 are schematic cross-sectional views of a semiconductor device manufactured by the semiconductor device manufacturing method according to the first embodiment. FIG. 2 is a cross-sectional view taken along the line AA′ of FIG. 1. In FIG. 1, the vertical direction is referred to as a first direction. In FIG. 1, the horizontal direction is referred to as a second direction. The second direction crosses the first direction. For example, the second direction is perpendicular to the first direction.

The semiconductor device manufactured by the semiconductor device manufacturing method according to the first embodiment is a transistor 100. The transistor 100 is an oxide semiconductor transistor in which a channel is formed in the oxide semiconductor. In the transistor 100, a gate electrode surrounds an oxide semiconductor layer in which a channel is formed. The transistor 100 is a so-called surrounding gate transistor (SGT). The transistor 100 is a so-called vertical transistor.

The transistor 100 includes a substrate 10, a lower electrode 12, an upper electrode 14, an oxide semiconductor layer 16, a gate electrode 18, a gate insulating layer 20, a lower insulating layer 22, and an upper insulating layer 24.

The substrate 10 is, for example, a semiconductor substrate. On the surface of the substrate 10, for example, an insulating layer is provided. The insulating layer is, for example, a silicon oxide.

The lower electrode 12 is provided on the substrate 10. The lower electrode 12 is provided below the oxide semiconductor layer 16. The lower electrode 12 is electrically connected to the oxide semiconductor layer 16. The lower electrode 12 is in contact with the oxide semiconductor layer 16. The lower electrode 12 functions as a source electrode or a drain electrode of the transistor 100.

The lower electrode 12 is a conductor containing indium (In). The lower electrode 12 includes, for example, an oxide conductor containing indium (In).

The lower electrode 12 contains, for example, indium (In), tin (Sn), and oxygen (O). The lower electrode 12 contains, for example, indium tin oxide. The lower electrode 12 is, for example, an indium tin oxide layer.

The upper electrode 14 is provided on the oxide semiconductor layer 16. The upper electrode 14 is electrically connected to the oxide semiconductor layer 16. The upper electrode 14 is in contact with, for example, the oxide semiconductor layer 16. The upper electrode 14 functions as a source electrode or a drain electrode of the transistor 100.

The upper electrode 14 is a conductor. The upper electrode 14 includes, for example, an oxide conductor. The upper electrode 14 is, for example, an oxide conductor layer.

The upper electrode 14 contains, for example, indium (In), tin (Sn), and oxygen (O). The upper electrode 14 contains, for example, indium tin oxide. The upper electrode 14 is, for example, an indium tin oxide layer.

The upper electrode 14 contains, for example, tin (Sn) and oxygen (O). The upper electrode 14 contains, for example, tin oxide. The upper electrode 14 is, for example, a tin oxide layer.

The upper electrode 14 contains, for example, a metal. The upper electrode 14 is, for example, a metal layer.

The upper electrode 14 contains, for example, tungsten (W), molybdenum (Mo), copper (Cu), aluminum (Al), titanium (Ti), or tantalum (Ta). The upper electrode 14 is, for example, a tungsten layer, a molybdenum layer, a copper layer, an aluminum layer, a titanium layer, or a tantalum layer.

The lower electrode 12 and the upper electrode 14 are formed of, for example, the same material. For example, the lower electrode 12 and the upper electrode 14 are oxide conductors containing indium (In), tin (Sn), and oxygen (O). The lower electrode 12 and the upper electrode 14 contain, for example, indium tin oxide. The lower electrode 12 and the upper electrode 14 are, for example, indium tin oxide layers.

The oxide semiconductor layer 16 is provided between the lower electrode 12 and the upper electrode 14. The oxide semiconductor layer 16 is in contact with, for example, the lower electrode 12. The oxide semiconductor layer 16 is in contact with, for example, the upper electrode 14.

In the oxide semiconductor layer 16, a channel serving as a current path is formed when the transistor 100 is turned on.

The oxide semiconductor layer 16 is an oxide semiconductor. The oxide semiconductor layer 16 is amorphous, for example.

The oxide semiconductor layer 16 contains, for example, zinc (Zn), oxygen (O), and at least one element selected from a group consisting of indium (In), gallium (Ga), silicon (Si), aluminum (Al), and tin (Sn). The oxide semiconductor layer 16 contains, for example, indium (In), gallium (Ga), zinc (Zn), and oxygen (O). The oxide semiconductor layer 16 contains, for example, indium gallium zinc oxide. The oxide semiconductor layer 16 is, for example, an indium gallium zinc oxide layer.

The oxide semiconductor layer 16 contains, for example, oxygen (O) and at least one element selected from a group consisting of titanium (Ti), zinc (Zn), and tungsten (W). For example, the oxide semiconductor layer 16 contains titanium oxide, zinc oxide, or tungsten oxide. The oxide semiconductor layer 16 is, for example, a titanium oxide layer, a zinc oxide layer, or a tungsten oxide layer.

The length of the oxide semiconductor layer 16 in the first direction is, for example, equal to or more than 80 nm and equal to or less than 200 nm. The length of the oxide semiconductor layer 16 in the second direction is, for example, equal to or more than 20 nm and equal to or less than 100 nm.

The first direction is a direction from the lower electrode 12 to the upper electrode 14. The second direction is a direction crossing the first direction. For example, the second direction is a direction perpendicular to the first direction.

The gate electrode 18 faces the oxide semiconductor layer 16. As shown in FIG. 2, the gate electrode 18 is provided so as to surround the oxide semiconductor layer 16. The gate electrode 18 is provided around the oxide semiconductor layer 16.

The gate electrode 18 is a conductor. The gate electrode 18 is, for example, a metal, a metal compound, or a semiconductor. The gate electrode 18 contains, for example, tungsten (W).

The length of the gate electrode 18 in the first direction is, for example, equal to or more than 20 nm and equal to or less than 100 nm.

The gate insulating layer 20 is provided between the oxide semiconductor layer 16 and the gate electrode 18. The gate insulating layer 20 is provided so as to surround the oxide semiconductor layer 16. The gate insulating layer 20 is provided between the lower electrode 12 and the upper electrode 14.

The gate insulating layer 20 is, for example, an oxide, a nitride, or an oxynitride. The gate insulating layer 20 contains, for example, silicon oxide, aluminum oxide, silicon nitride, aluminum nitride, or silicon oxynitride. The gate insulating layer 20 is, for example, a silicon oxide layer, an aluminum oxide layer, a silicon nitride layer, an aluminum nitride layer, or a silicon oxynitride layer.

The gate insulating layer 20 may have, for example, a stacked structure. The gate insulating layer 20 is, for example, a stacked structure of a nitride and an oxide. The gate insulating layer 20 has, for example, a stacked structure of a silicon nitride layer and a silicon oxide layer. The thickness of the gate insulating layer 20 is, for example, equal to or more than 2 nm and equal to or less than 10 nm.

The lower insulating layer 22 is provided on the lower electrode 12. The lower insulating layer 22 is provided between the lower electrode 12 and the gate electrode 18.

The upper insulating layer 24 is provided on the gate electrode 18. For example, the upper insulating layer 24 is provided between the gate electrode 18 and the upper electrode 14.

The upper insulating layer 24 is an insulator. The upper insulating layer 24 is, for example, an oxide, a nitride, or an oxynitride. The upper insulating layer 24 contains, for example, silicon (Si) and oxygen (O). The upper insulating layer 24 contains, for example, silicon oxide. The upper insulating layer 24 is, for example, a silicon oxide layer.

Next, an example of the semiconductor device manufacturing method according to the first embodiment will be described.

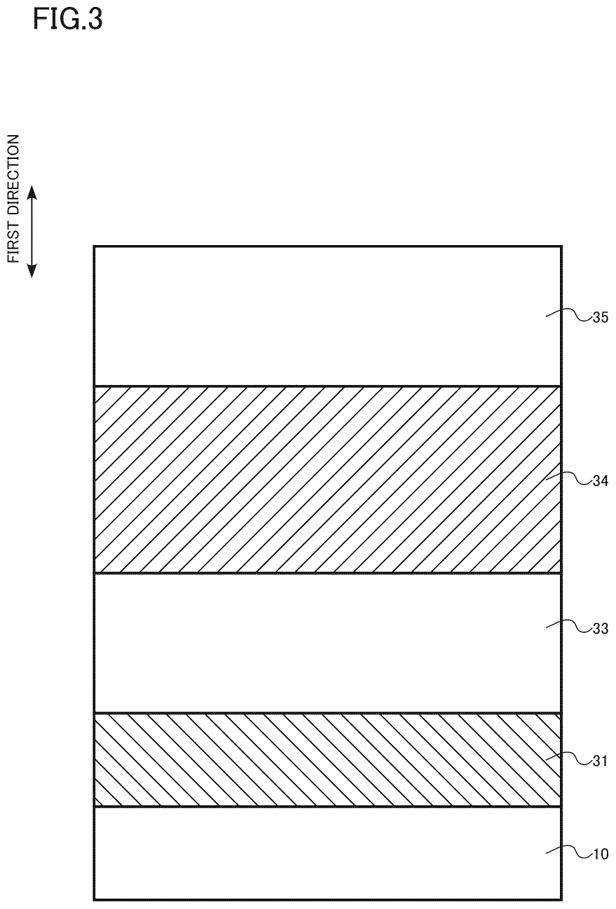

FIGS. 3 to 11 are schematic cross-sectional views showing an example of the semiconductor device manufacturing method according to the first embodiment. FIGS. 3 to 11 each show a cross section corresponding to FIG. 1. FIGS. 3 to 11 are diagrams showing an example of a method for manufacturing the transistor 100.

Hereinafter, a case where the lower electrode 12 is an indium tin oxide layer, the upper electrode 14 is an indium tin oxide layer, the oxide semiconductor layer 16 is an indium gallium zinc oxide layer, the gate electrode 18 is a tungsten layer, the gate insulating layer 20 is a silicon oxide layer, the lower insulating layer 22 is a silicon oxide layer, and the upper insulating layer 24 is a silicon oxide layer will be described as an example.

First, a first indium tin oxide film 31, a first silicon oxide film 33, a tungsten film 34, and a second silicon oxide film 35 are stacked on the substrate 10 in this order in the first direction (FIG. 3). The first indium tin oxide film 31, the first silicon oxide film 33, the tungsten film 34, and the second silicon oxide film 35 are formed by using, for example, a chemical vapor deposition method (CVD method). The substrate 10 is, for example, a silicon substrate having a silicon oxide layer formed on its surface.

A part of the first indium tin oxide film 31 finally becomes the lower electrode 12. A part of the first silicon oxide film 33 finally becomes the lower insulating layer 22. A part of the tungsten film 34 finally becomes the gate electrode 18. A part of the second silicon oxide film 35 finally becomes the upper insulating layer 24.

The first indium tin oxide film 31 is an example of the first conductive film. The first conductive film is a conductive film containing indium (In). The first conductive film is, for example, an oxide conductor containing indium (In).

The first silicon oxide film 33 is an example of the first insulating film. The first insulating film is, for example, an oxide, a nitride, or an oxynitride.

The tungsten film 34 is an example of the second conductive film. The second conductive film is, for example, a metal, a metal compound, or a semiconductor.

The second silicon oxide film 35 is an example of the second insulating film. The second insulating film is, for example, an oxide, a nitride, or an oxynitride.

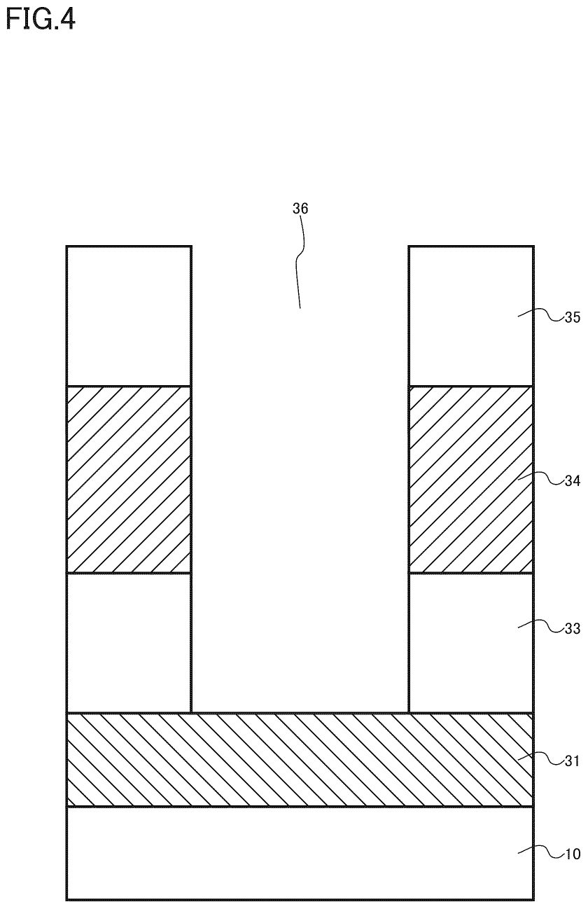

Then, an opening 36 that penetrates the second silicon oxide film 35, the tungsten film 34, and the first silicon oxide film 33 from the surface of the second silicon oxide film 35 to reach the first indium tin oxide film 31 is formed (FIG. 4). The opening 36 is formed by using, for example, a lithography method and a reactive ion etching method (RIE method).

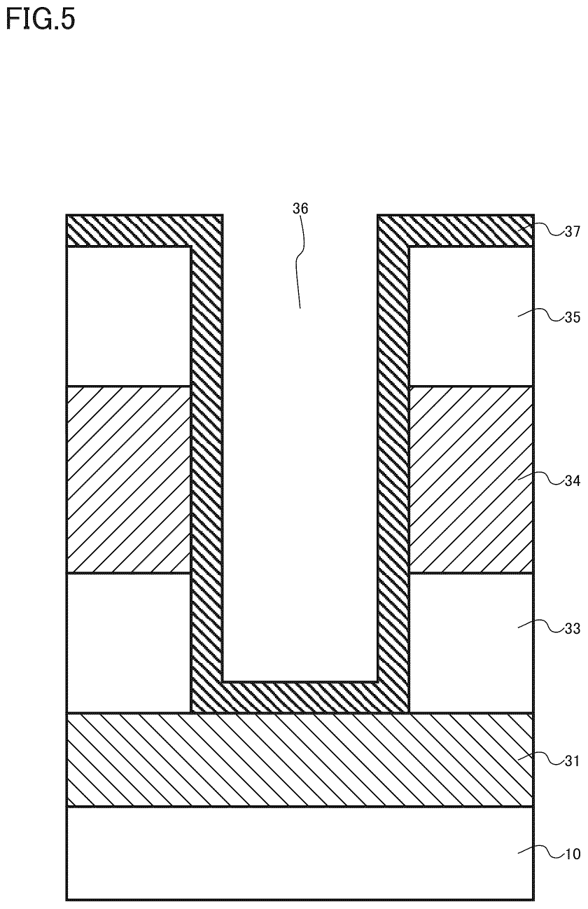

Then, a third silicon oxide film 37 is formed inside the opening 36 (FIG. 5). The third silicon oxide film 37 is formed in contact with the bottom and side surfaces of the opening 36. The third silicon oxide film 37 is formed by using, for example, a CVD method. A part of the third silicon oxide film 37 finally becomes the gate insulating layer 20. The thickness of the third silicon oxide film 37 is, for example, equal to or more than 2 nm and equal to or less than 10 nm.

The third silicon oxide film 37 is an example of the third insulating film. The third insulating film is, for example, an oxide, a nitride, or an oxynitride. The third insulating film contains, for example, silicon oxide, aluminum oxide, silicon nitride, aluminum nitride, or silicon oxynitride.

The third insulating film may be, for example, a stacked film. The third insulating film is, for example, a stacked film of a nitride film and an oxide film. The third insulating film is, for example, a stacked film of a silicon nitride film and a silicon oxide film.

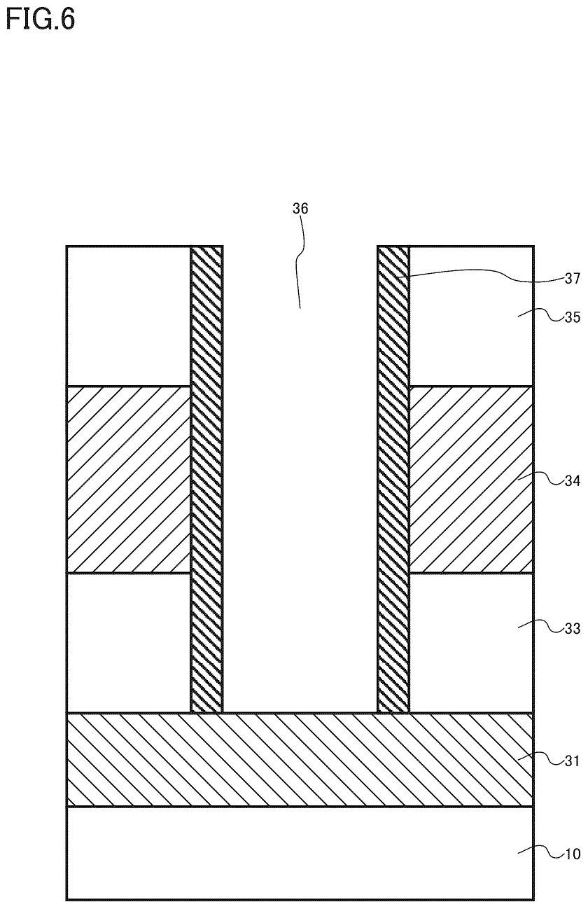

Then, the third silicon oxide film 37 at the bottom of the opening 36 is removed to expose the first indium tin oxide film 31 at the bottom of the opening 36 (FIG. 6). The third silicon oxide film 37 is etched by using, for example, an RIE method.

When removing the third silicon oxide film 37 at the bottom of the opening 36, for example, indium (In) contained in the first indium tin oxide film 31 scatters to adhere to the surface of the third silicon oxide film 37 in contact with the side surface of the opening 36. Thereafter, at least a part of indium (In) adhering to the surface of the third silicon oxide film 37 diffuses into the third silicon oxide film 37, for example.

As a post-treatment after removing the third silicon oxide film 37 at the bottom of the opening 36, wet etching may be performed. For wet etching, for example, a chemical solution containing dilute hydrofluoric acid is used.

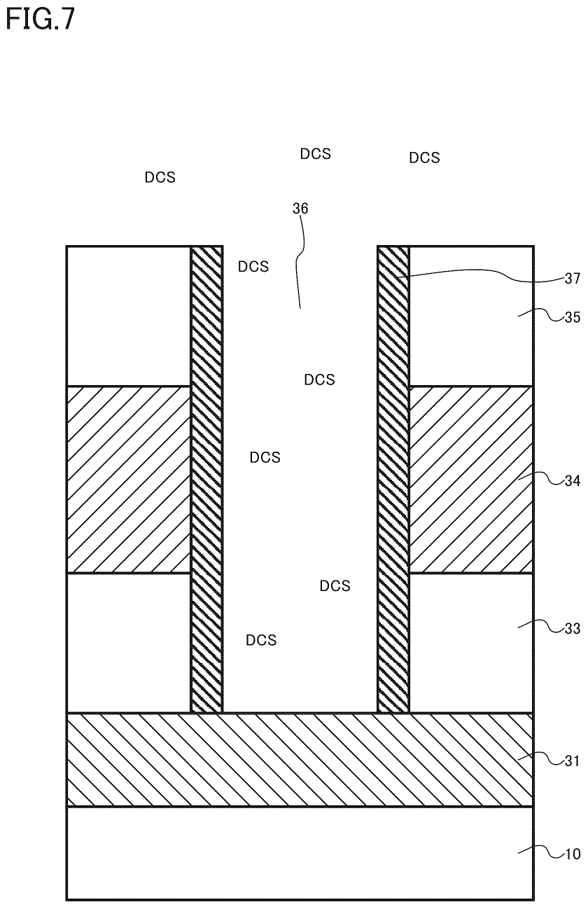

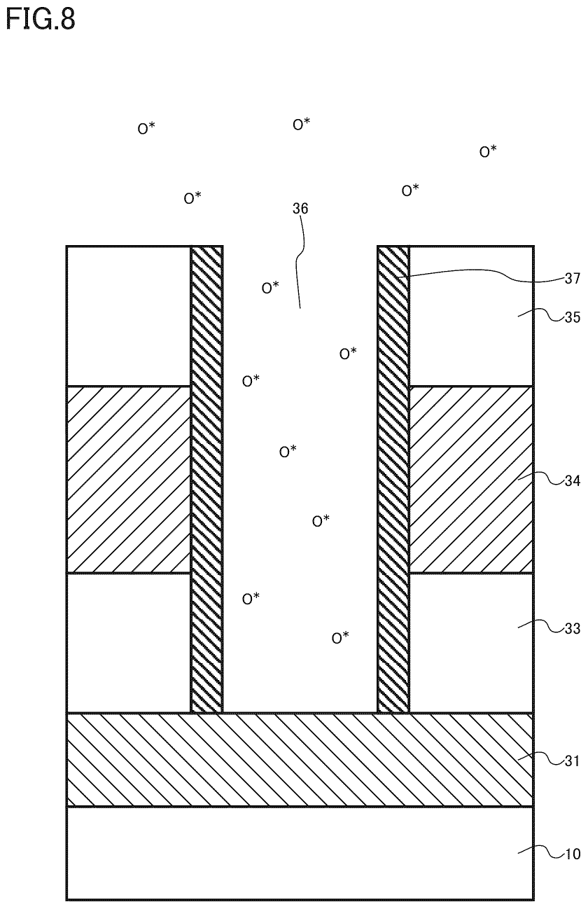

Then, at least one of pre-cleaning of semiconductor film formation using a gas containing dichlorosilane (DCS) (FIG. 7) and pre-cleaning of semiconductor film formation using a gas containing oxygen plasma (FIG. 8) is performed. Both the pre-cleaning of semiconductor film formation using a gas containing dichlorosilane (DCS) and the pre-cleaning of semiconductor film formation using a gas containing oxygen plasma may be performed.

The temperature of the pre-cleaning of semiconductor film formation is, for example, equal to or more than 20° C. and equal to or less than 300° C. The temperature of the substrate 10 during the pre-cleaning of semiconductor film formation is, for example, equal to or more than 20° C. and equal to or less than 300° C.

The pre-cleaning of semiconductor film formation is performed at a pressure less than atmospheric pressure. The pre-cleaning of semiconductor film formation is performed in a vacuum state.

By the pre-cleaning of semiconductor film formation using a gas containing dichlorosilane (DCS), for example, indium (In) adhering to the surface of the third silicon oxide film 37 or indium (In) diffused into the third silicon oxide film 37 is removed.

By the pre-cleaning of semiconductor film formation using a gas containing oxygen plasma, for example, indium (In) adhering to the surface of the third silicon oxide film 37 or indium (In) diffused into the third silicon oxide film 37 is oxidized.

The pre-cleaning of semiconductor film formation using a gas containing dichlorosilane (DCS) is an example of the first treatment. The gas containing dichlorosilane is an example of the first gas.

The first gas contains silicon (Si). The first gas further contains, for example, carbon (C), hydrogen (H), or a halogen element. The first gas further contains, for example, chlorine (Cl).

Examples of the first gas include an organic silane gas and an inorganic silane gas. Examples of the organic silane gas include tris(dimethylamino) silane (((CH₃)₂N)₃SiH), monomethylaminosilane (((CH₃)HN)SiH₃), and bisdimethylaminosilane (((CH₃)₂N)₂Si(CH₃)₂). Examples of the inorganic silane gas include silane (SiH₄), disilane (Si₂H₆), dichlorosilane (SiH₂Cl₂), hexachlorodisilane ((SiCl₃)₂), and trichlorosilane (HSiCl₃).

The pre-cleaning of semiconductor film formation using a gas containing oxygen plasma is an example of the second treatment. The gas containing oxygen plasma is an example of the second gas. As the pre-cleaning of semiconductor film formation using a gas containing oxygen plasma, for example, ashing can be applied.

The second gas is a gas containing oxygen (O). The second gas contains oxygen plasma, oxygen gas (O₂), or ozone gas (O₃). The second gas containing oxygen plasma contains oxygen radicals and oxygen ions.

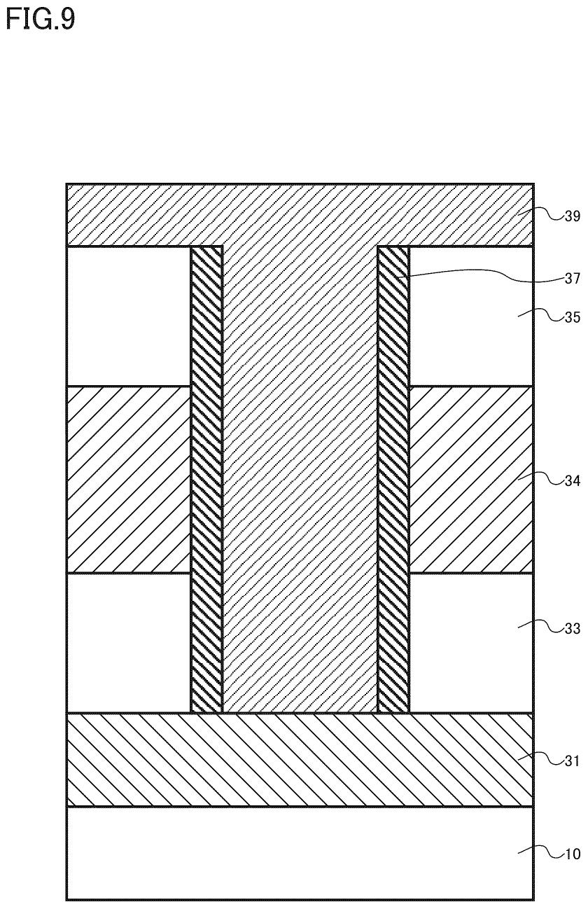

Then, an indium gallium zinc oxide film 39 is formed in the opening 36 (FIG. 9). For example, an indium gallium zinc oxide film 39 is buried in the opening 36. A part of the indium gallium zinc oxide film 39 finally becomes the oxide semiconductor layer 16. The indium gallium zinc oxide film 39 is formed by using, for example, a CVD method.

The indium gallium zinc oxide film 39 is formed at a pressure less than atmospheric pressure. The indium gallium zinc oxide film 39 is formed in a vacuum state.

The indium gallium zinc oxide film 39 is formed after the pre-cleaning of semiconductor film formation without exposing the substrate 10 to an atmosphere with a pressure equal to or more than atmospheric pressure. In other words, the substrate 10 is kept in a vacuum state from the end of the pre-cleaning of semiconductor film formation until the end of the formation of the indium gallium zinc oxide film 39. The pre-cleaning of semiconductor film formation and the formation of the indium gallium zinc oxide film 39 are performed consecutively. The pre-cleaning of semiconductor film formation and the formation of the indium gallium zinc oxide film 39 are performed as a so-called in-situ process.

The indium gallium zinc oxide film 39 is an example of a semiconductor film. The semiconductor film is, for example, an oxide semiconductor film.

The semiconductor film contains, for example, zinc (Zn), oxygen (O), and at least one element selected from a group consisting of indium (In), gallium (Ga), silicon (Si), aluminum (Al), and tin (Sn). The semiconductor film contains, for example, indium (In), gallium (Ga), zinc (Zn) and oxygen (O). The semiconductor film contains, for example, indium gallium zinc oxide.

The semiconductor film contains, for example, oxygen (O) and at least one element selected from a group consisting of titanium (Ti), zinc (Zn), and tungsten (W). The semiconductor film contains, for example, titanium oxide, zinc oxide, or tungsten oxide.

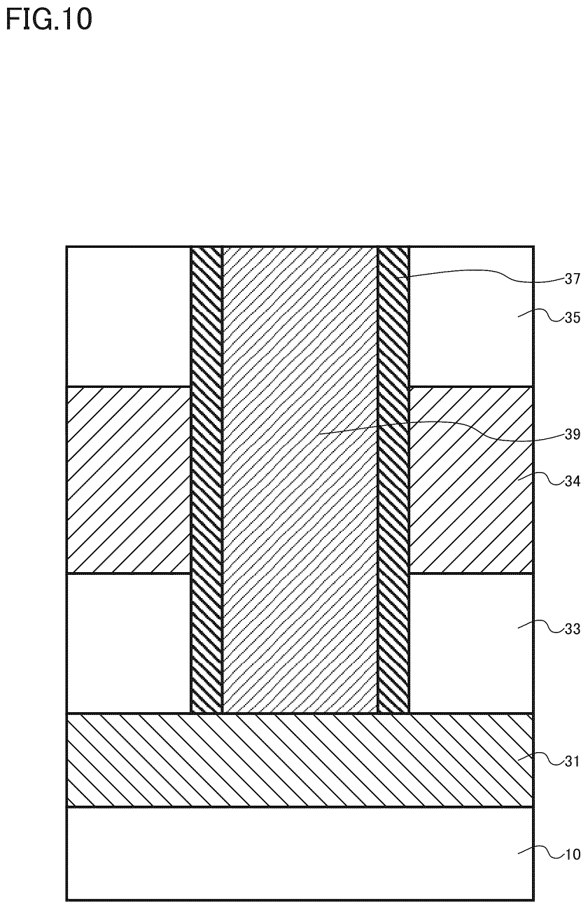

Then, an upper portion of the indium gallium zinc oxide film 39 is removed to expose the surface of the second silicon oxide film 35 (FIG. 10). The indium gallium zinc oxide film 39 is removed by using, for example, an RIE method.

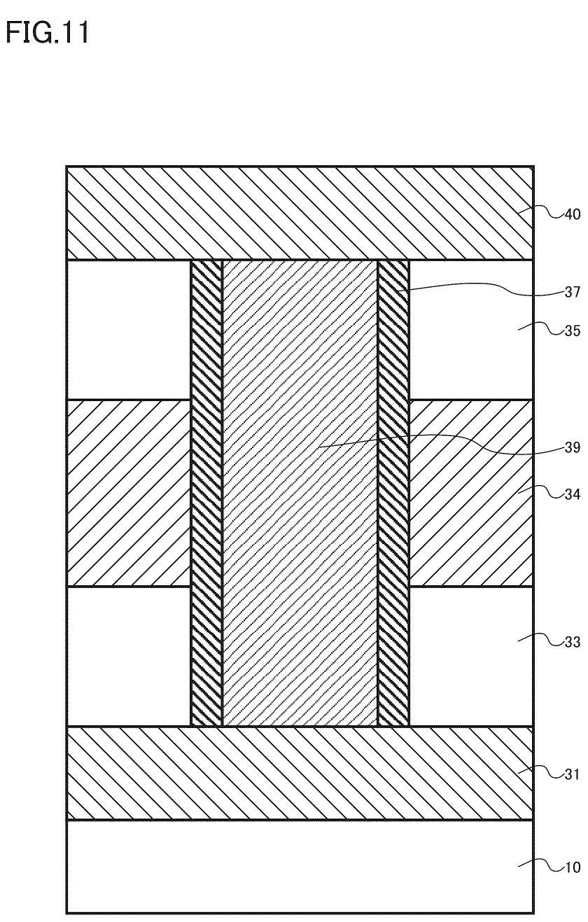

Then, a second indium tin oxide film 40 is formed (FIG. 11). The second indium tin oxide film 40 is formed by using, for example, a CVD method. A part of the second indium tin oxide film 40 finally becomes the upper electrode 14.

By the manufacturing method described above, the transistor 100 shown in FIGS. 1 and 2 is manufactured.

Next, the function and effect of the semiconductor device manufacturing method according to the first embodiment will be described.

For example, as a semiconductor device manufacturing method according to a comparative example, a case will be considered in which the pre-cleaning of semiconductor film formation is not performed before the formation of a semiconductor film in the semiconductor device manufacturing method according to the first embodiment. In this case, there is a problem that the leakage current of the gate insulating layer of the transistor to be manufactured increases.

As described above, when removing the third silicon oxide film 37 at the bottom of the opening 36, for example, indium (In) contained in the first indium tin oxide film 31 scatters to adhere to the surface of the third silicon oxide film 37 in contact with the side surface of the opening 36.

Thereafter, at least a part of indium (In) adhering to the surface of the third silicon oxide film 37 diffuses into the third silicon oxide film 37 which becomes a gate insulating layer later. After removing the third silicon oxide film 37 at the bottom of the opening 36, when the substrate 10 is exposed to an atmosphere with a pressure equal to or more than atmospheric pressure, it is believed that the diffusion of indium (In) is promoted due to, for example, the influence of moisture in the atmosphere.

Indium (In) present on the surface of the third silicon oxide film 37 or indium (In) diffused into the third silicon oxide film 37 remains even after the transistor is manufactured, which is believed to be the cause of the increase in leakage current of the gate insulating layer.

In the semiconductor device manufacturing method according to the first embodiment, the pre-cleaning of semiconductor film formation is performed before the indium gallium zinc oxide film 39 is formed. The indium gallium zinc oxide film 39 is formed after the pre-cleaning of semiconductor film formation without exposing the substrate 10 to an atmosphere with a pressure equal to or more than atmospheric pressure. By the manufacturing method described above, the leakage current of the gate insulating layer 20 of the transistor 100 to be manufactured is suppressed.

When the first treatment using a first gas containing silicon (Si) is performed as the pre-cleaning of semiconductor film formation, indium (In) present on the surface of the third silicon oxide film 37 or indium (In) diffused into the third silicon oxide film 37 is removed by the first treatment. (In) is removed by reacting with the first gas. Since indium (In) is removed from the third silicon oxide film 37, the leakage current of the gate insulating layer 20 of the transistor 100 to be manufactured is suppressed.

When the second treatment using a second gas containing oxygen (O) is performed as the pre-cleaning of semiconductor film formation, indium (In) present on the surface of the third silicon oxide film 37 or indium (In) diffused into the third silicon oxide film 37 becomes an indium oxide by the second treatment. Indium (In) reacts with the second gas and is oxidized to become an indium oxide. Since indium (In) in the third silicon oxide film 37 is oxidized, the leakage current of the gate insulating layer 20 of the transistor 100 to be manufactured is suppressed.

After the pre-cleaning of semiconductor film formation, when the substrate 10 is exposed to an atmosphere with a pressure equal to or more than atmospheric pressure, indium (In) sublimates from the surface of the indium gallium zinc oxide film 39 exposed at the bottom of the opening 36, for example. Sublimated indium (in) may adhere to the surface of the third silicon oxide film 37 in contact with the side surface of the opening 36. In addition, indium (In) adhering to the surface of the third silicon oxide film 37 may diffuse into the third silicon oxide film 37 when the substrate 10 is exposed to an atmosphere with a pressure equal to or more than atmospheric pressure. Therefore, before the formation of the indium gallium zinc oxide film 39 after the pre-cleaning of semiconductor film formation, when the substrate 10 is exposed to an atmosphere with a pressure equal to or more than atmospheric pressure, the leakage current of the gate insulating layer of the transistor to be manufactured may increase.

In the semiconductor device manufacturing method according to the first embodiment, the indium gallium zinc oxide film 39 is formed after the pre-cleaning of semiconductor film formation without exposing the substrate 10 to an atmosphere with a pressure equal to or more than atmospheric pressure. Therefore, the adhesion of indium (in) to the surface of the third silicon oxide film 37 due to sublimation of indium (in) and the diffusion of indium (in) into the third silicon oxide film 37 are suppressed. Therefore, the leakage current of the gate insulating layer 20 of the transistor 100 manufactured by the semiconductor device manufacturing method according to the first embodiment is suppressed.

The temperature of the pre-cleaning of semiconductor film formation is preferably equal to or more than 20° C. and equal to or less than 300° C., more preferably equal to or more than 50° C. and equal to or less than 250° C., and even more preferably equal to or more than 100° C. and equal to or less than 200° C. By setting the temperature of the pre-cleaning of semiconductor film formation to be equal to or more than the lower limit values, the removal of indium (In) in the first treatment and the oxidation of indium (In) in the second treatment are promoted. In addition, by setting the temperature of the pre-cleaning of semiconductor film formation to be equal to or less than the upper limit values, for example, process damage caused by thermal stress to the first conductive film and the second conductive film is reduced.

As described above, according to the first embodiment, it is possible to realize a semiconductor device manufacturing method in which the leakage current of the gate insulating layer is suppressed.

### Second Embodiment

A semiconductor device manufacturing method according to a second embodiment includes: forming a first conductive film containing indium (In) on a substrate; forming a first insulating film on the first conductive film; forming an intermediate insulating film on the first insulating film; forming a second insulating film on the intermediate insulating film; forming an opening penetrating the second insulating film, the intermediate insulating film, and the first insulating film to reach the first conductive film; forming a third insulating film in the opening so as to be in contact with bottom and side surfaces of the opening; removing the third insulating film at a bottom of the opening to expose the first conductive film at the bottom of the opening; performing at least one treatment selected from a group including a first treatment using a first gas containing silicon (Si) and a second treatment using a second gas containing oxygen (O); forming a semiconductor film in the opening without exposing the substrate to an atmosphere with a pressure equal to or more than atmospheric pressure after the at least one treatment; removing the intermediate insulating film; and forming a second conductive film in a region where the intermediate insulating film has been removed. The semiconductor device manufacturing method according to the second embodiment is different from the semiconductor device manufacturing method according to the first embodiment in that the second conductive film is formed after the semiconductor film is formed in the opening. Hereinafter, the description of a part of the content overlapping the first embodiment may be omitted.

The semiconductor device manufactured by the semiconductor device manufacturing method according to the second embodiment is an oxide semiconductor transistor similar to the transistor 100 according to the first embodiment.

Next, an example of the semiconductor device manufacturing method according to the second embodiment will be described.

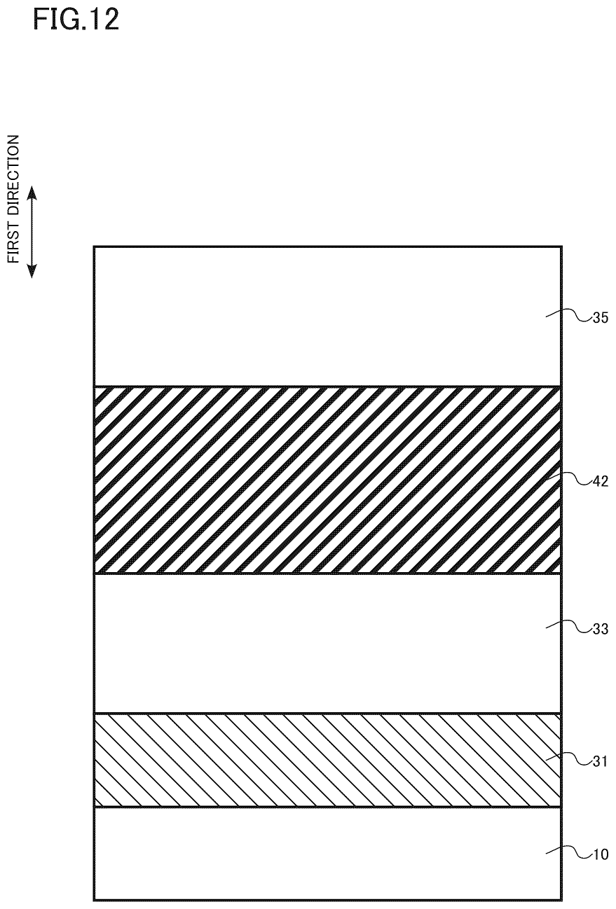

FIGS. 12 to 17 are schematic cross-sectional views showing an example of the semiconductor device manufacturing method according to the second embodiment. FIGS. 12 to 17 each show a cross section corresponding to FIG. 1 of the first embodiment.

First, a first indium tin oxide film 31, a first silicon oxide film 33, a silicon nitride film 42, and a second silicon oxide film 35 are stacked on a substrate 10 in this order in the first direction (FIG. 12). The first indium tin oxide film 31, the first silicon oxide film 33, the silicon nitride film 42, and the second silicon oxide film 35 are formed by using, for example, a CVD method. The substrate 10 is, for example, a silicon substrate having a silicon oxide layer formed on its surface.

A part of the first indium tin oxide film 31 finally becomes the lower electrode 12. A part of the first silicon oxide film 33 finally becomes the lower insulating layer 22. A part of the second silicon oxide film 35 finally becomes the upper insulating layer 24.

The first indium tin oxide film 31 is an example of the first conductive film. The first conductive film is a conductive film containing indium (In). The first conductive film is, for example, an oxide conductor containing indium (In).

The first silicon oxide film 33 is an example of the first insulating film. The first insulating film is, for example, an oxide, a nitride, or an oxynitride.

The silicon nitride film 42 is an example of an intermediate insulating film. The intermediate insulating film is, for example, a nitride or an oxynitride.

The second silicon oxide film 35 is an example of the second insulating film. The second insulating film is, for example, an oxide, a nitride, or an oxynitride.

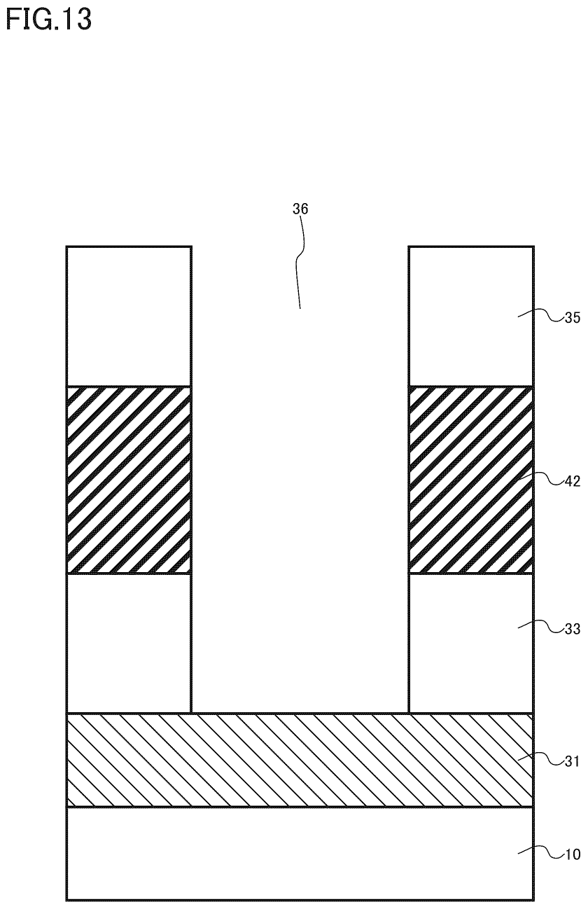

Then, an opening 36 that penetrates the second silicon oxide film 35, the silicon nitride film 42, and the first silicon oxide film 33 from the surface of the second silicon oxide film 35 to reach the first indium tin oxide film 31 is formed (FIG. 13). The opening 36 is formed by using, for example, a lithography method and an RIE method.

Then, a third silicon oxide film 37 is formed in the opening 36. The third silicon oxide film 37 is formed in contact with the bottom and side surfaces of the opening 36. The third silicon oxide film 37 is formed by using, for example, a CVD method. A part of the third silicon oxide film 37 finally becomes the gate insulating layer 20.

The third silicon oxide film 37 is an example of the third insulating film. The third insulating film is, for example, an oxide, a nitride, or an oxynitride. The third insulating film contains, for example, silicon oxide, aluminum oxide, silicon nitride, aluminum nitride, or silicon oxynitride.

Then, the third silicon oxide film 37 at the bottom of the opening 36 is removed to expose the first indium tin oxide film 31. The third silicon oxide film 37 is etched by using, for example, an RIE method.

As a post-treatment after removing the third silicon oxide film 37 at the bottom of the opening 36, wet etching may be performed.

Then, at least one of pre-cleaning of semiconductor film formation using a gas containing dichlorosilane (DCS) and pre-cleaning of semiconductor film formation using a gas containing oxygen plasma is performed. Both the pre-cleaning of semiconductor film formation using a gas containing dichlorosilane (DCS) and the pre-cleaning of semiconductor film formation using a gas containing oxygen plasma may be performed.

The temperature of the pre-cleaning of semiconductor film formation is, for example, equal to or more than 10° C. and equal to or less than 300° C. The temperature of the substrate 10 during the pre-cleaning of semiconductor film formation is, for example, equal to or more than 20° C. and equal to or less than 300° C.

By the pre-cleaning of semiconductor film formation using a gas containing dichlorosilane (DCS), for example, indium (In) present on the surface or inside of the third silicon oxide film 37 in contact with the side surface of the opening 36 is removed.

By the pre-cleaning of semiconductor film formation using a gas containing oxygen plasma, for example, indium (In) present on the surface or inside of the third silicon oxide film 37 in contact with the side surface of the opening 36 is removed.

The pre-cleaning of semiconductor film formation using a gas containing dichlorosilane is an example of the first treatment. The gas containing dichlorosilane is an example of the first gas.

The first gas contains silicon (Si). The first gas further contains, for example, carbon (C), hydrogen (H), or a halogen element. The first gas further contains, for example, chlorine (Cl).

The first gas is, for example, silane, dichlorosilane (DCS), tris(dimethylamino) silane (TDMAS), or hexachlorodisilane (HCDS).

The pre-cleaning of semiconductor film formation using a gas containing oxygen plasma is an example of the second treatment. The gas containing oxygen plasma is an example of the second gas.

The second gas is a gas containing oxygen (O). The second gas contains oxygen plasma, oxygen gas (O₂), or ozone gas (O₃). The gas containing oxygen plasma contains oxygen radicals and oxygen ions. The second gas containing oxygen plasma contains oxygen radicals and oxygen ions. Then, an indium gallium zinc oxide film 39 is formed in the opening 36.

The indium gallium zinc oxide film 39 is formed after the pre-cleaning of semiconductor film formation without exposing the substrate 10 to an atmosphere with a pressure equal to or more than atmospheric pressure. In other words, the substrate 10 is kept in a vacuum state from the end of the pre-cleaning of semiconductor film formation until the start of the formation of the indium gallium zinc oxide film 39. The pre-cleaning of semiconductor film formation and the formation of the indium gallium zinc oxide film 39 are performed consecutively. The pre-cleaning of semiconductor film formation and the formation of the indium gallium zinc oxide film 39 are performed as a so-called in-situ process.

The indium gallium zinc oxide film 39 is an example of a semiconductor film. The semiconductor film is, for example, an oxide semiconductor film.

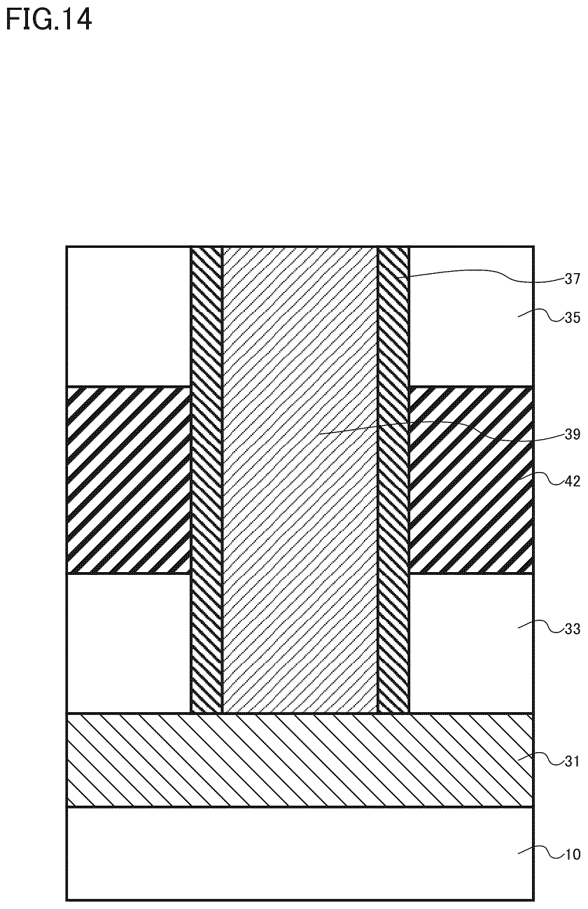

Then, an upper portion of the indium gallium zinc oxide film 39 is removed to expose the surface of the second silicon oxide film 35 (FIG. 14).

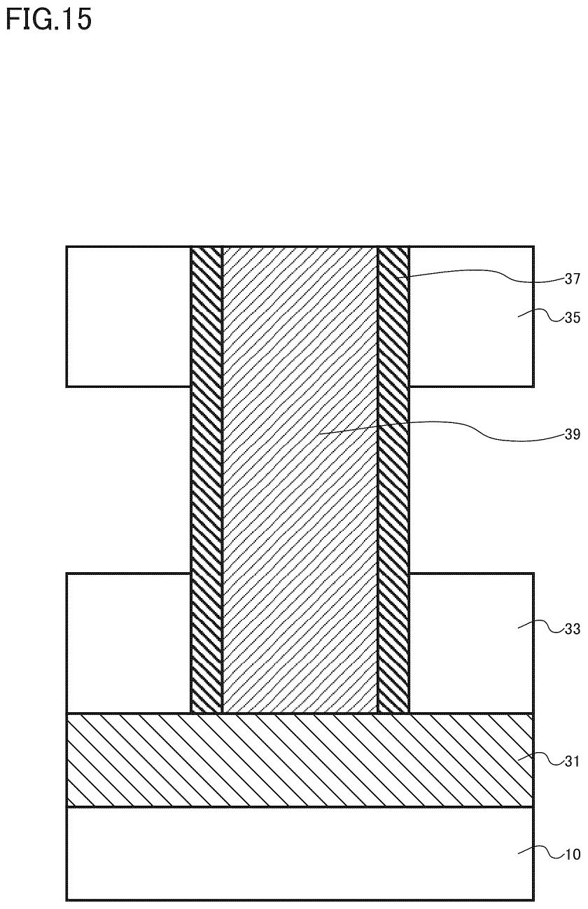

Then, the silicon nitride film 42 is removed (FIG. 15). The silicon nitride film 42 is removed by using, for example, a wet etching method.

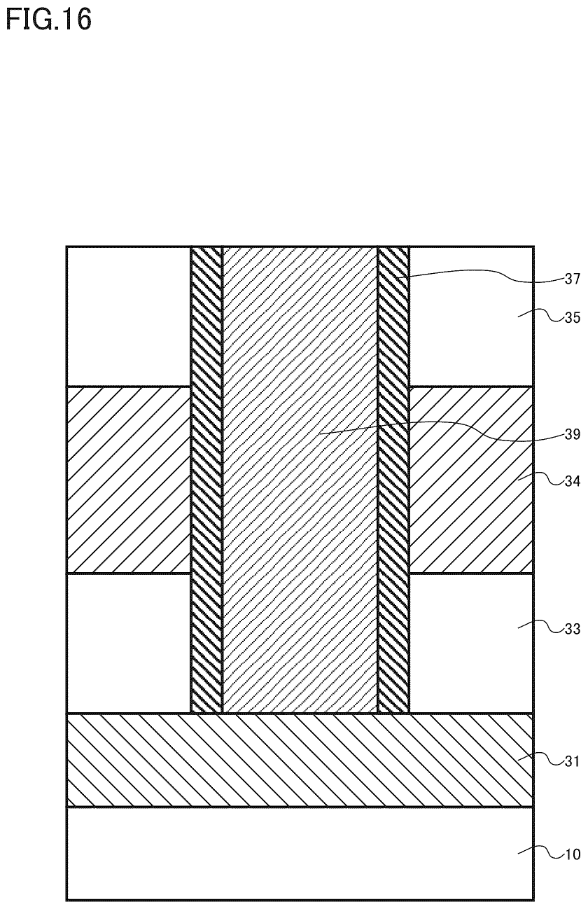

Then, a tungsten film 34 is formed in a region where the silicon nitride film 42 has been removed (FIG. 16). A part of the tungsten film 34 finally becomes the gate electrode 18.

The tungsten film 34 is an example of the second conductive film. The second conductive film is, for example, a metal, a metal compound, or a semiconductor.

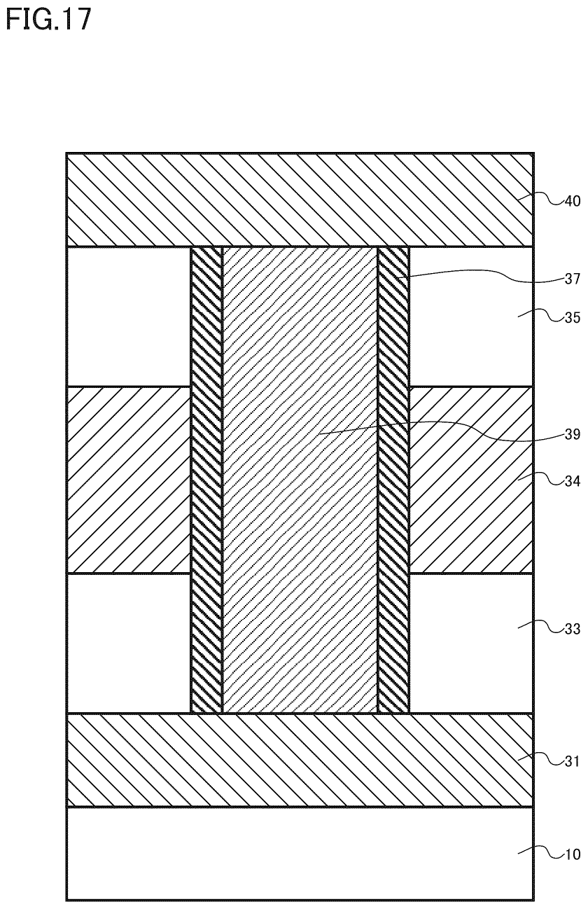

Then, a second indium tin oxide film 40 is formed (FIG. 17). The second indium tin oxide film 40 is formed by using, for example, a CVD method. A part of the second indium tin oxide film 40 finally becomes the upper electrode 14.

By the manufacturing method described above, the transistor according to the second embodiment is manufactured.

According to the semiconductor device manufacturing method according to the second embodiment, similarly to the semiconductor device manufacturing method according to the first embodiment, the leakage current of the gate insulating layer of the transistor to be manufactured is suppressed by performing pre-cleaning of semiconductor film formation.

As described above, according to the second embodiment, it is possible to realize a semiconductor device manufacturing method in which the leakage current of the gate insulating layer is suppressed.

### Third Embodiment

A semiconductor manufacturing apparatus according to a third embodiment includes a first supply pipe for supplying a first gas containing silicon (Si), a second supply pipe for supplying a first source gas containing indium (In), a third supply pipe for supplying a second source gas containing oxygen (O), and a chamber to which the first supply pipe, the second supply pipe, and the third supply pipe are connected. The semiconductor manufacturing apparatus according to the third embodiment is a semiconductor manufacturing apparatus to realize the semiconductor device manufacturing method according to the first or second embodiment. Hereinafter, the description of a part of the content overlapping the first or second embodiment may be omitted.

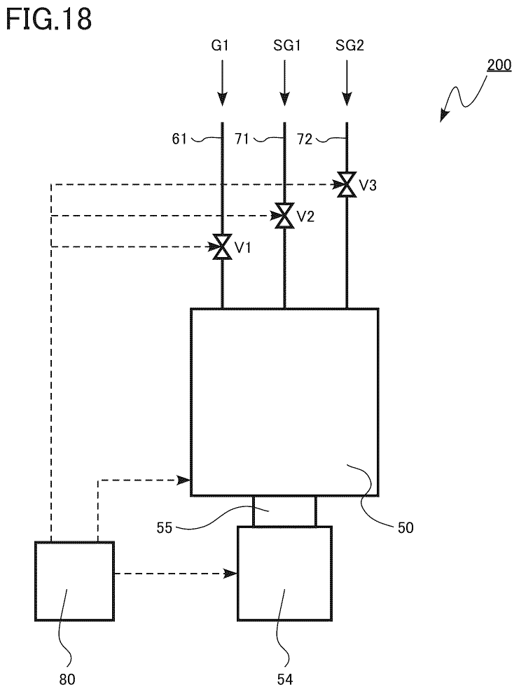

FIG. 18 is a schematic diagram of the semiconductor manufacturing apparatus according to the third embodiment. The semiconductor manufacturing apparatus according to the third embodiment is a film forming apparatus 200 that forms a film on a substrate. The film forming apparatus 200 is a single wafer processing type film forming apparatus that forms a film on one substrate in one film forming process.

The film forming apparatus 200 can realize the semiconductor device manufacturing method according to the first or second embodiment. The film forming apparatus 200 is a film forming apparatus capable of performing the first treatment and the formation of a semiconductor film after the first treatment in the manufacturing method according to the first or second embodiment.

The film forming apparatus 200 includes a process chamber 50, a load-lock chamber 54, a gate valve 55, a first pre-treatment gas supply pipe 61, a first source gas supply pipe 71, a second source gas supply pipe 72, and a control circuit 80. In addition, the film forming apparatus 200 includes a first valve V1, a second valve V2, and a third valve V3.

In the process chamber 50, the pre-cleaning of semiconductor film formation for the substrate and the formation of the semiconductor film on the substrate are performed consecutively. The process chamber 50 is an example of a chamber.

The substrate is placed on a holder provided in the process chamber 50, for example. For example, an exhaust pipe and a vacuum pump (not shown) are connected to the process chamber 50. The inside of the process chamber 50 can be maintained in a vacuum state.

The load-lock chamber 54 is provided to load the substrate into the process chamber 50 and unload the substrate from the process chamber 50 without opening the process chamber 50 to the atmosphere. For example, an exhaust pipe and a vacuum pump (not shown) are connected to the load-lock chamber 54. The inside of the load-lock chamber 54 can be maintained in a vacuum state.

The gate valve 55 is provided between the load-lock chamber 54 and the process chamber 50. The gate valve 55 has a function of maintaining the process chamber 50 in a vacuum state. The substrate is allowed to pass through the gate valve 55.

The first pre-treatment gas supply pipe 61 is connected to the process chamber 50. The first pre-treatment gas supply pipe 61 is an example of the first supply pipe. The first pre-treatment gas supply pipe 61 supplies a first gas G1 containing silicon (Si) to the process chamber 50.

The first valve V1 is provided in the first pre-treatment gas supply pipe 61. The start and stop of the supply of the first gas G1 are controlled by using the first valve V1.

The first source gas supply pipe 71 is connected to the process chamber 50. The first source gas supply pipe 71 is an example of the second supply pipe. The first source gas supply pipe 71 supplies a first source gas SG1 containing indium (In) to the process chamber 50.

The first source gas SG1 further contains, for example, gallium (Ga) and zinc (Zn). The first source gas SG1 contains, for example, trimethylindium, trimethylgallium, and dimethylzinc.

The second valve V2 is provided in the first source gas supply pipe 71. The start and stop of the supply of the first source gas SG1 are controlled by using the second valve V2.

The second source gas supply pipe 72 is connected to the process chamber 50. The second source gas supply pipe 72 is an example of the third supply pipe. The second source gas supply pipe 72 supplies a second source gas SG2 containing oxygen (O) to the process chamber 50.

The second source gas SG2 is, for example, an ozone gas.

The third valve V3 is provided in the second source gas supply pipe 72. The start and stop of the supply of the second source gas SG2 are controlled by using the third valve V3.

The control circuit 80 has a function of controlling the processing of the film forming apparatus 200 on the substrate. The control circuit 80 controls the opening and closing of the first valve V1. The control circuit 80 controls the opening and closing of the second valve V2. The control circuit 80 controls the opening and closing of the third valve V3. The control circuit 80 controls the opening and closing of the gate valve 55.

The control circuit 80 controls the loading of the substrate into the process chamber 50 and the unloading of the substrate from the process chamber 50. The control circuit 80 controls the pressure or temperature of the inside of the process chamber 50 or the pressure or temperature of the inside of the load-lock chamber 54.

The control circuit 80 is, for example, an electronic circuit. The control circuit 80 includes, for example, hardware and software.

The control circuit 80 includes, for example, a central processing unit (CPU). The control circuit 80 includes, for example, a storage device. The storage device included in the control circuit 80 is, for example, a semiconductor memory, a solid state device (SSD), or a hard disk.

The control circuit 80 can control the film forming apparatus 200 in order to realize the semiconductor device manufacturing method according to the first embodiment or the semiconductor device manufacturing method according to the second embodiment. The control circuit 80 controls the loading of the substrate into the process chamber 50. The control circuit 80 controls the supply of the first gas G1 containing silicon (Si) into the process chamber 50 using the first pre-treatment gas supply pipe 61. The control circuit 80 controls the supply of the first source gas SG1 into the process chamber 50 using the first source gas supply pipe 71 and the supply of the second source gas SG2 into the process chamber 50 using the second source gas supply pipe 72. The control circuit 80 controls the formation of the semiconductor film on the substrate. The control circuit 80 controls the unloading of the substrate out of the process chamber 50.

According to the film forming apparatus 200 according to the third embodiment, the pre-cleaning of semiconductor film formation and the formation of the semiconductor film can be performed consecutively in the same process chamber 50. Therefore, the semiconductor film can be formed without exposing the substrate to an atmosphere with a pressure equal to or more than atmospheric pressure between the pre-cleaning of semiconductor film formation and the formation of the semiconductor film.

As described above, according to the third embodiment, it is possible to realize a semiconductor manufacturing apparatus capable of manufacturing a semiconductor device in which the leakage current of a gate insulating layer is suppressed.

### Fourth Embodiment

A semiconductor manufacturing apparatus according to a fourth embodiment includes a first supply pipe for supplying a first gas containing silicon (Si), a second supply pipe for supplying a first source gas containing indium (In), a third supply pipe for supplying a second source gas containing oxygen (O), a first chamber to which the first supply pipe is connected, a second chamber to which the second supply pipe and the third supply pipe are connected, and a transfer path that connects the first chamber and the second chamber to each other so that the inside of the transfer path can be maintained at a pressure less than atmospheric pressure. The semiconductor manufacturing apparatus according to the fourth embodiment is a semiconductor manufacturing apparatus to realize the semiconductor device manufacturing method according to the first or second embodiment. The semiconductor manufacturing apparatus according to the fourth embodiment is different from the semiconductor manufacturing apparatus according to the third embodiment in that the semiconductor manufacturing apparatus according to the fourth embodiment includes two chambers of a first chamber and a second chamber and a transfer path. Hereinafter, the description of a part of the content overlapping the first, second, or third embodiment may be omitted.

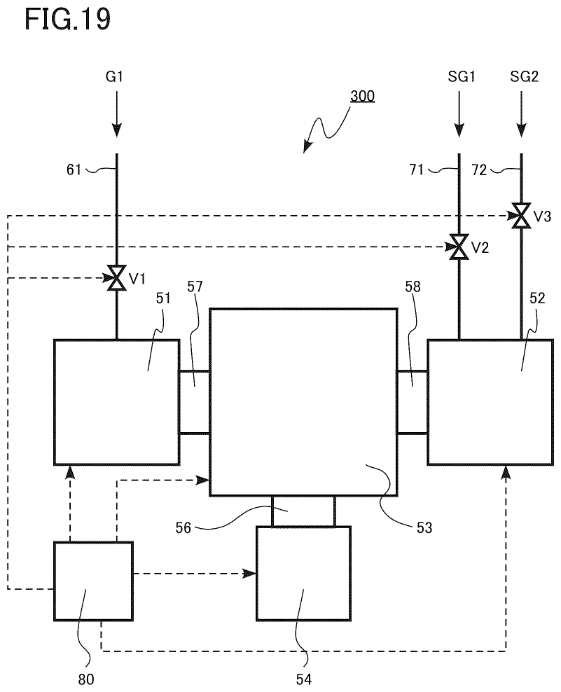

FIG. 19 is a schematic diagram of the semiconductor manufacturing apparatus according to the fourth embodiment. The semiconductor manufacturing apparatus according to the fourth embodiment is a film forming apparatus 300 that forms a film on a substrate. The film forming apparatus 300 is a single wafer processing type film forming apparatus that forms a film on one substrate in one film forming process.

The film forming apparatus 300 can realize the semiconductor device manufacturing method according to the first or second embodiment. The film forming apparatus 300 is a film forming apparatus capable of performing the first treatment and the formation of a semiconductor film after the first treatment in the manufacturing method according to the first or second embodiment.

The film forming apparatus 300 includes a first process chamber 51, a second process chamber 52, a transfer chamber 53, a load-lock chamber 54, a first gate valve 56, a second gate valve 57, a third gate valve 58, a first pre-treatment gas supply pipe 61, a first source gas supply pipe 71, a second source gas supply pipe 72, and a control circuit 80. In addition, the film forming apparatus 300 includes a first valve V1, a second valve V2, and a third valve V3.

In the first process chamber 51, the pre-cleaning of semiconductor film formation for the substrate is performed. The first process chamber 51 is an example of the first chamber.

The substrate is placed on a holder provided in the first process chamber 51, for example. For example, an exhaust pipe and a vacuum pump (not shown) are connected to the first process chamber 51. The inside of the first process chamber 51 can be maintained in a vacuum state.

In the second process chamber 52, a semiconductor film is formed on the substrate. The second process chamber 52 is an example of the second chamber.

The substrate is placed on a holder provided in the second process chamber 52, for example. For example, an exhaust pipe and a vacuum pump (not shown) are connected to the second process chamber 52. The inside of the second process chamber 52 can be maintained in a vacuum state.

The transfer chamber 53 has a function of transferring the substrate between the load-lock chamber 54, the first process chamber 51, and the second process chamber 52. The transfer chamber 53 is an example of the transfer path. In the transfer chamber 53, for example, a transfer robot for transferring the substrate is provided.

For example, an exhaust pipe and a vacuum pump (not shown) are connected to the transfer chamber 53. The inside of the transfer chamber 53 can be maintained in a vacuum state. The inside of the transfer chamber 53 can be maintained at a pressure less than atmospheric pressure.

The load-lock chamber 54 is provided to load the substrate into the transfer chamber 53 and unload the substrate from the transfer chamber 53 without opening the transfer chamber 53 to the atmosphere. For example, an exhaust pipe and a vacuum pump (not shown) are connected to the load-lock chamber 54. The inside of the load-lock chamber 54 can be maintained in a vacuum state.

The first gate valve 56 is provided between the load-lock chamber 54 and the transfer chamber 53. The first gate valve 56 has a function of maintaining the transfer chamber 53 in a vacuum state. The substrate is allowed to pass through the first gate valve 56.

The second gate valve 57 is provided between the first process chamber 51 and the transfer chamber 53. The substrate is allowed to pass through the second gate valve 57. The second gate valve 57 has a function of maintaining the first process chamber 51 in a vacuum state. The substrate is allowed to pass through the second gate valve 57.

The third gate valve 58 is provided between the second process chamber 52 and the transfer chamber 53. The third gate valve 58 has a function of maintaining the second process chamber 52 in a vacuum state. The substrate is allowed to pass through the third gate valve 58.

The first pre-treatment gas supply pipe 61 is connected to the first process chamber 51. The first pre-treatment gas supply pipe 61 is an example of the first supply pipe. The first pre-treatment gas supply pipe 61 supplies the first gas G1 containing silicon (Si) to the first process chamber 51.

The first valve V1 is provided in the first pre-treatment gas supply pipe 61. The start and stop of the supply of the first gas G1 are controlled by using the first valve V1.

The first source gas supply pipe 71 is connected to the second process chamber 52. The first source gas supply pipe 71 is an example of the second supply pipe. The first source gas supply pipe 71 supplies the first source gas SG1 containing indium (In) to the second process chamber 52.

The first source gas SG1 further contains, for example, gallium (Ga) and zinc (Zn). The first source gas SG1 contains, for example, trimethylindium, trimethylgallium, and dimethylzinc.

The second valve V2 is provided in the first source gas supply pipe 71. The start and stop of the supply of the first source gas SG1 are controlled by using the second valve V2.

The second source gas supply pipe 72 is connected to the second process chamber 52. The second source gas supply pipe 72 is an example of the third supply pipe. The second source gas supply pipe 72 supplies the second source gas SG2 containing oxygen (O) to the second process chamber 52.

The second source gas SG2 is, for example, an ozone gas.

The third valve V3 is provided in the second source gas supply pipe 72. The start and stop of the supply of the second source gas SG2 are controlled by using the third valve V3.

The control circuit 80 has a function of controlling the processing of the film forming apparatus 300 on the substrate. The control circuit 80 controls the opening and closing of the first valve V1. The control circuit 80 controls the opening and closing of the second valve V2. The control circuit 80 controls the opening and closing of the third valve V3. The control circuit 80 controls the opening and closing of the first gate valve 56. The control circuit 80 controls the opening and closing of the second gate valve 57. The control circuit 80 controls the opening and closing of the third gate valve 58.

The control circuit 80 controls the loading of the substrate into the first process chamber 51 and the unloading of the substrate from the first process chamber 51. The control circuit 80 controls the loading of the substrate into the second process chamber 52 and the unloading of the substrate from the second process chamber 52. The control circuit 80 controls the pressure or temperature of the inside of the first process chamber 51, the pressure or temperature of the inside of the second process chamber 52, the pressure or temperature of the inside of the transfer chamber 53, or the pressure or temperature of the inside of the load-lock chamber 54.

The control circuit 80 is, for example, an electronic circuit. The control circuit 80 includes, for example, hardware and software.

The control circuit 80 includes, for example, a CPU. The control circuit 80 includes, for example, a storage device. The storage device included in the control circuit 80 is, for example, a semiconductor memory, an SSD, or a hard disk.

The control circuit 80 can control the film forming apparatus 300 in order to realize the semiconductor device manufacturing method according to the first embodiment or the semiconductor device manufacturing method according to the second embodiment. The control circuit 80 controls the loading of the substrate into the first process chamber 51. The control circuit 80 controls the supply of the first gas G1 containing silicon (Si) into the first process chamber 51 using the first pre-treatment gas supply pipe 61. The control circuit 80 controls the transfer of the substrate in the transfer chamber 53 maintained at a pressure less than atmospheric pressure. The control circuit 80 controls the loading of the substrate into the second process chamber 52. The control circuit 80 controls the supply of the first source gas SG1 into the second process chamber 52 using the first source gas supply pipe 71 and the supply of the second source gas SG2 into the second process chamber 52 using the second source gas supply pipe 72. The control circuit 80 controls the formation of the semiconductor film on the substrate. The control circuit 80 controls the unloading of the substrate out of the second process chamber 52.

According to the film forming apparatus 300 according to the fourth embodiment, the pre-cleaning of semiconductor film formation in the first process chamber 51 and the formation of the semiconductor film in the second process chamber 52 can be performed consecutively within the same apparatus. By providing the transfer chamber 53, the inside of which can be maintained at a pressure less than atmospheric pressure, between the first process chamber 51 and the second process chamber 52, the semiconductor film can be formed without exposing the substrate to an atmosphere with a pressure equal to or more than atmospheric pressure between the pre-cleaning of semiconductor film formation and the formation of the semiconductor film.

### Modification Examples

A semiconductor manufacturing apparatus according to a modification example of the fourth embodiment is different from the semiconductor manufacturing apparatus according to the fourth embodiment in that the transfer chamber 53 is an example of the first chamber and the third gate valve 58 is an example of the transfer path.

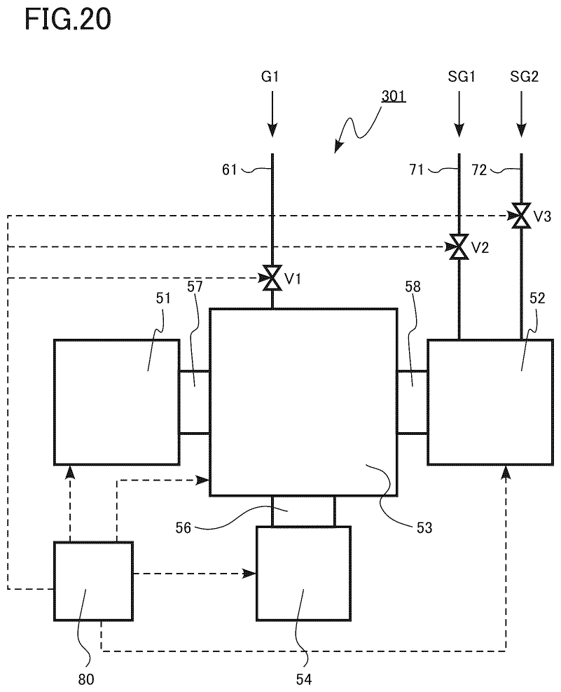

FIG. 20 is a schematic diagram of the semiconductor manufacturing apparatus according to the modification example of the fourth embodiment. The semiconductor manufacturing apparatus according to the modification example of the fourth embodiment is a film forming apparatus 301 that forms a film on a substrate.

The film forming apparatus 301 includes a first process chamber 51, a second process chamber 52, a transfer chamber 53, a load-lock chamber 54, a first gate valve 56, a second gate valve 57, a third gate valve 58, a first pre-treatment gas supply pipe 61, a first source gas supply pipe 71, a second source gas supply pipe 72, and a control circuit 80. In addition, the film forming apparatus 301 includes a first valve V1, a second valve V2, and a third valve V3.

In the first process chamber 51, for example, a film is formed on a substrate. In the first process chamber 51, for example, an insulating film is formed on the substrate.

The substrate is placed on a holder provided in the first process chamber 51, for example. For example, an exhaust pipe and a vacuum pump (not shown) are connected to the first process chamber 51. The inside of the first process chamber 51 can be maintained in a vacuum state.

In the second process chamber 52, a semiconductor film is formed on the substrate. The second process chamber 52 is an example of the second chamber.

The substrate is placed on a holder provided in the second process chamber 52, for example. For example, an exhaust pipe and a vacuum pump (not shown) are connected to the second process chamber 52. The inside of the second process chamber 52 can be maintained in a vacuum state.

The transfer chamber 53 has a function of transferring the substrate between the load-lock chamber 54, the first process chamber 51, and the second process chamber 52. In the transfer chamber 53, for example, a transfer robot for transferring the substrate is provided.

In addition, in the transfer chamber 53, the pre-cleaning of semiconductor film formation for the substrate is performed. The transfer chamber 53 is an example of the first chamber.

For example, an exhaust pipe and a vacuum pump (not shown) are connected to the transfer chamber 53. The inside of the transfer chamber 53 can be maintained in a vacuum state.

The third gate valve 58 is provided between the second process chamber 52 and the transfer chamber 53. The third gate valve 58 is an example of the transfer path. The third gate valve 58 has a function of maintaining the second process chamber 52 in a vacuum state. The substrate is allowed to pass through the third gate valve.

The first pre-treatment gas supply pipe 61 is connected to the transfer chamber 53. The first pre-treatment gas supply pipe 61 is an example of the first supply pipe. The first pre-treatment gas supply pipe 61 supplies the first gas G1 containing silicon (Si) to the first process chamber 51.

The first valve V1 is provided in the first pre-treatment gas supply pipe 61. The start and stop of the supply of the first gas G1 are controlled by using the first valve V1.

According to the film forming apparatus 301 according to the modification example of the fourth embodiment, the pre-cleaning of semiconductor film formation in the transfer chamber 53 and the formation of the semiconductor film in the second process chamber 52 can be performed consecutively within the same apparatus. By providing the third gate valve 58, the inside of which can be maintained at a pressure less than atmospheric pressure, between the transfer chamber 53 and the second process chamber 52, the semiconductor film can be formed without exposing the substrate to an atmosphere with a pressure equal to or more than atmospheric pressure between the pre-cleaning of semiconductor film formation and the formation of the semiconductor film.

In addition, as a film forming apparatus according to another modification example of the fourth embodiment, it is also possible to connect the first pre-treatment gas supply pipe 61 to the load-lock chamber 54 to perform the pre-cleaning of semiconductor film formation in the load-lock chamber 54. In the case of the film forming apparatus according to this modification example, the load-lock chamber 54 is an example of the first chamber, the second process chamber 52 is an example of the second chamber, and the transfer chamber 53 is an example of the transfer path.

As described above, according to the fourth embodiment and its modification example, it is possible to realize a semiconductor manufacturing apparatus capable of manufacturing a semiconductor device in which the leakage current of a gate insulating layer is suppressed.

### Fifth Embodiment

A semiconductor manufacturing apparatus according to a fifth embodiment includes a first supply pipe for supplying a second gas containing oxygen (O), a second supply pipe for supplying a first source gas containing indium (In), a third supply pipe for supplying a second source gas containing oxygen (O), and a chamber to which the first supply pipe, the second supply pipe, and the third supply pipe are connected. The semiconductor manufacturing apparatus according to the fifth embodiment is a semiconductor manufacturing apparatus to realize the semiconductor device manufacturing method according to the first or second embodiment. In addition, the semiconductor manufacturing apparatus according to the fifth embodiment is different from the semiconductor manufacturing apparatus according to the third embodiment in that the first supply pipe supplies the second gas instead of the first gas. Hereinafter, the description of a part of the content overlapping the first, second, or third embodiment may be omitted.

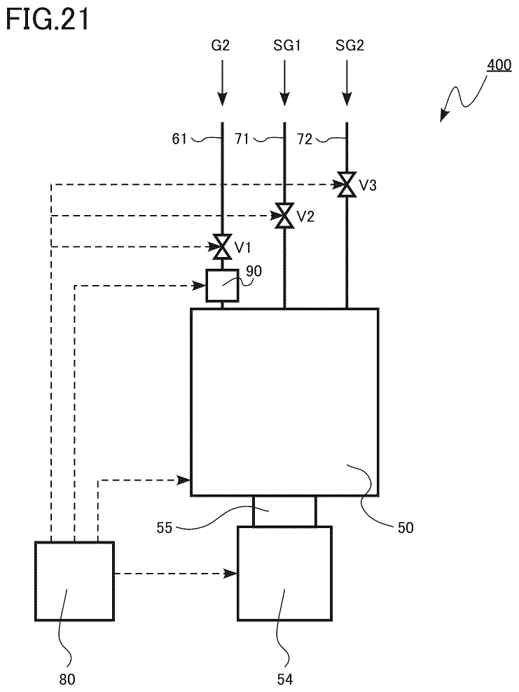

FIG. 21 is a schematic diagram of the semiconductor manufacturing apparatus according to the fifth embodiment. The semiconductor manufacturing apparatus according to the fifth embodiment is a film forming apparatus 400 that forms a film on a substrate. The film forming apparatus 400 is a single wafer processing type film forming apparatus that forms a film on one substrate in one film forming process.

The film forming apparatus 400 can realize the semiconductor device manufacturing method according to the first or second embodiment. The film forming apparatus 400 is a film forming apparatus capable of performing the second treatment and the formation of a semiconductor film after the second treatment in the manufacturing method according to the first or second embodiment.

The film forming apparatus 400 includes a process chamber 50, a load-lock chamber 54, a gate valve 55, a first pre-treatment gas supply pipe 61, a first source gas supply pipe 71, a second source gas supply pipe 72, and a control circuit 80. In addition, the film forming apparatus 400 includes a first valve V1, a second valve V2, and a third valve V3. The first pre-treatment gas supply pipe 61 includes a plasma generator 90.

In the process chamber 50, the pre-cleaning of semiconductor film formation for the substrate and the formation of the semiconductor film on the substrate are performed consecutively. The process chamber 50 is an example of a chamber.

The first pre-treatment gas supply pipe 61 is connected to the process chamber 50. The first pre-treatment gas supply pipe 61 is an example of the first supply pipe. The first pre-treatment gas supply pipe 61 supplies a second gas G2 containing oxygen (O) to the process chamber 50.

The first valve V1 is provided in the first pre-treatment gas supply pipe 61. The start and stop of the supply of the second gas G2 are controlled by using the first valve V1.

The first pre-treatment gas supply pipe 61 includes the plasma generator 90. The plasma generator 90 generates plasma using, for example, a high-frequency induction coil. The plasma generator 90 has a function of generating oxygen plasma. The plasma generator 90 generates oxygen plasma from oxygen gas (O₂), for example. The generated oxygen plasma is supplied from the first pre-treatment gas supply pipe 61 to the process chamber 50.

According to the film forming apparatus 400 according to the fifth embodiment, the pre-cleaning of semiconductor film formation and the formation of the semiconductor film can be performed consecutively in the same process chamber 50. Therefore, the semiconductor film can be formed without exposing the substrate to an atmosphere with a pressure equal to or more than atmospheric pressure between the pre-cleaning of semiconductor film formation and the formation of the semiconductor film.

As a film forming apparatus according to a modification example of the fifth embodiment, the first pre-treatment gas supply pipe 61 may not include the plasma generator 90. In this case, for example, oxygen gas (Oz) for ozone gas (O₃) is supplied from the first pre-treatment gas supply pipe 61 to the process chamber 50 as the second gas G2 containing oxygen (O).

As described above, according to the fifth embodiment and its modification example, it is possible to realize a semiconductor manufacturing apparatus capable of manufacturing a semiconductor device in which the leakage current of a gate insulating layer is suppressed.

### Sixth Embodiment

A semiconductor manufacturing apparatus according to a sixth embodiment includes a first supply pipe for supplying a second gas containing oxygen (O), a second supply pipe for supplying a first source gas containing indium (In), a third supply pipe for supplying a second source gas containing oxygen (O), a first chamber to which the first supply pipe is connected, a second chamber to which the second supply pipe and the third supply pipe are connected, and a transfer path that connects the first chamber and the second chamber to each other so that the inside of the transfer path can be maintained at a pressure less than atmospheric pressure. The semiconductor manufacturing apparatus according to the sixth embodiment is a semiconductor manufacturing apparatus to realize the semiconductor device manufacturing method according to the first or second embodiment. In addition, the semiconductor manufacturing apparatus according to the sixth embodiment is different from the semiconductor manufacturing apparatus according to the fourth embodiment in that the first supply pipe supplies the second gas instead of the first gas. Hereinafter, the description of a part of the content overlapping the first, second, or fourth embodiment may be omitted.

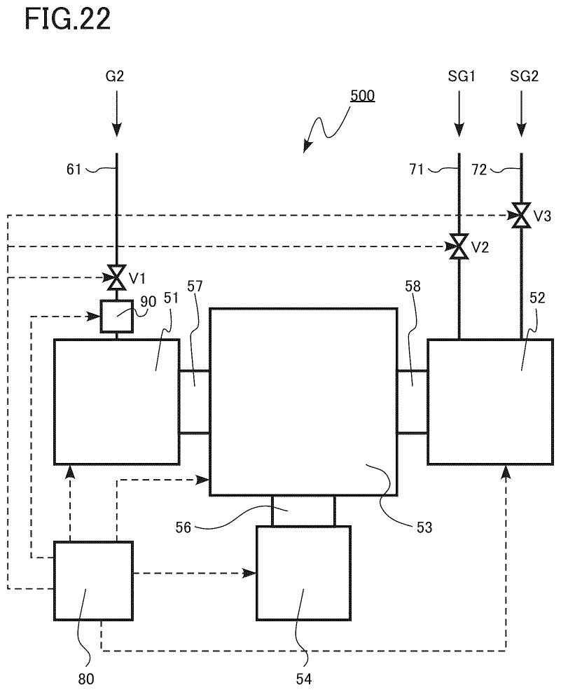

FIG. 22 is a schematic diagram of the semiconductor manufacturing apparatus according to the sixth embodiment. The semiconductor manufacturing apparatus according to the sixth embodiment is a film forming apparatus 500 that forms a film on a substrate. The film forming apparatus 500 is a single wafer processing type film forming apparatus that forms a film on one substrate in one film forming process.

The film forming apparatus 500 can realize the semiconductor device manufacturing method according to the first or second embodiment. The film forming apparatus 500 is a film forming apparatus capable of performing the second treatment and the formation of a semiconductor film after the second treatment in the manufacturing method according to the first or second embodiment.

The film forming apparatus 500 includes a first process chamber 51, a second process chamber 52, a transfer chamber 53, a load-lock chamber 54, a first gate valve 56, a second gate valve 57, a third gate valve 58, a first pre-treatment gas supply pipe 61, a first source gas supply pipe 71, a second source gas supply pipe 72, and a control circuit 80. In addition, the film forming apparatus 500 includes a first valve V1, a second valve V2, and a third valve V3. The first pre-treatment gas supply pipe 61 includes a plasma generator 90.

In the first process chamber 51, the pre-cleaning of semiconductor film formation for the substrate is performed. The first process chamber 51 is an example of the first chamber.

In the second process chamber 52, a semiconductor film is formed on the substrate. The second process chamber 52 is an example of the second chamber.

The first pre-treatment gas supply pipe 61 is connected to the first process chamber 51. The first pre-treatment gas supply pipe 61 is an example of the first supply pipe. The first pre-treatment gas supply pipe 61 supplies the second gas G2 containing oxygen (O) to the first process chamber 51.

The first valve V1 is provided in the first pre-treatment gas supply pipe 61. The start and stop of the supply of the second gas G2 are controlled by using the first valve V1.

The first pre-treatment gas supply pipe 61 includes the plasma generator 90. The plasma generator 90 generates plasma using, for example, a high-frequency induction coil. The plasma generator 90 has a function of generating oxygen plasma. The plasma generator 90 generates oxygen plasma from oxygen gas (O₂), for example. The generated oxygen plasma is supplied from the first pre-treatment gas supply pipe 61 to the first process chamber 51.

According to the film forming apparatus 500 according to the sixth embodiment, the pre-cleaning of semiconductor film formation in the first process chamber 51 and the formation of the semiconductor film in the second process chamber 52 can be performed consecutively within the same apparatus. By providing the transfer chamber 53, the inside of which can be maintained at a pressure less than atmospheric pressure, between the first process chamber 51 and the second process chamber 52, the semiconductor film can be formed without exposing the substrate to an atmosphere with a pressure equal to or more than atmospheric pressure between the pre-cleaning of semiconductor film formation and the formation of the semiconductor film.

As a film forming apparatus according to a modification example of the sixth embodiment, the first pre-treatment gas supply pipe 61 may not include the plasma generator 90. In this case, for example, oxygen gas (O₂) or ozone gas (O₃) is supplied from the first pre-treatment gas supply pipe 61 to the first process chamber 51 as the second gas G2 containing oxygen (O).

In addition, as a film forming apparatus according to another modification example of the sixth embodiment, it is also possible to connect the first pre-treatment gas supply pipe 61 to the transfer chamber 53 to perform the pre-cleaning of semiconductor film formation in the transfer chamber 53. In the case of the film forming apparatus according to this modification example, the transfer chamber 53 is an example of the first chamber, the second process chamber 52 is an example of the second chamber, and the third gate valve 58 is an example of the transfer path.

In addition, as a film forming apparatus according to still another modification example of the sixth embodiment, it is also possible to connect the first pre-treatment gas supply pipe 61 to the load-lock chamber 54 to perform the pre-cleaning of semiconductor film formation in the load-lock chamber 54. In the case of the film forming apparatus according to this modification example, the load-lock chamber 54 is an example of the first chamber, the second process chamber 52 is an example of the second chamber, and the transfer chamber 53 is an example of the transfer path.

As described above, according to the sixth embodiment and its modification examples, it is possible to realize a semiconductor manufacturing apparatus capable of manufacturing a semiconductor device in which the leakage current of a gate insulating layer is suppressed.

In the third to sixth embodiments, a single wafer processing type film forming apparatus that forms a film on one substrate in one film forming process has been described as an example. However, the film forming apparatus may be a batch processing type film forming apparatus that forms films on a plurality of substrates in one film forming process.

While certain embodiments have been described, these embodiments have been presented by way of example only, and are not intended to limit the scope of the inventions. Indeed, the semiconductor device manufacturing method and the semiconductor manufacturing apparatus described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device manufacturing method, comprising:
forming a first conductive film containing indium (In) on a substrate;
forming a first insulating film on the first conductive film;
forming a second conductive film on the first insulating film;
forming a second insulating film on the second conductive film;
forming an opening penetrating the second insulating film, the second conductive film, and the first insulating film to reach the first conductive film;
forming a third insulating film in the opening so as to be in contact with bottom and side surface of the opening;
removing the third insulating film at a bottom of the opening to expose the first conductive film at the bottom of the opening;
performing at least one treatment selected from a group consisting of a first treatment using a first gas containing silicon (Si) and a second treatment using a second gas containing oxygen (O); and
forming a semiconductor film in the opening after the at least one treatment without exposing the substrate to an atmosphere having a pressure equal to or more than atmospheric pressure.

2. The semiconductor device manufacturing method according to claim 1,
wherein the semiconductor film is in contact with the first conductive film.

3. The semiconductor device manufacturing method according to claim 1,
wherein a temperature of the at least one treatment is equal to or less than 300° C.

4. The semiconductor device manufacturing method according to claim 1,
wherein the first gas further contains carbon (C), hydrogen (H), or chlorine (Cl).

5. The semiconductor device manufacturing method according to claim 1,
wherein the second gas contains oxygen plasma, oxygen gas (O₂), or ozone gas (O₃).

6. The semiconductor device manufacturing method according to claim 1,
wherein, indium (In) adheres to the third insulating film in contact with the side surface of the opening in the removing the third insulating film at the bottom of the opening.

7. The semiconductor device manufacturing method according to claim 6,
wherein the first treatment removes indium (In) adhering to the third insulating film in contact with the side surface of the opening.

8. The semiconductor device manufacturing method according to claim 6,
wherein the second treatment oxidizes indium (In) adhering to the third insulating film in contact with the side surface of the opening.

9. The semiconductor device manufacturing method according to claim 1,
wherein the first conductive film further contains tin (Sn) and oxygen (O).

10. The semiconductor device manufacturing method according to claim 1,
wherein the semiconductor film is an oxide semiconductor.

11. The semiconductor device manufacturing method according to claim 1,
wherein the third insulating film contains silicon (Si) and oxygen (O).

12. A semiconductor manufacturing apparatus, comprising:
a first supply pipe supplying at least one gas selected from a group consisting of a first gas containing silicon (Si) and a second gas containing oxygen (O);
a second supply pipe supplying a first source gas containing indium (In);
a third supply pipe supplying a second source gas containing oxygen (O); and
a chamber connected with the first supply pipe, the second supply pipe, and the third supply pipe.

13. The semiconductor manufacturing apparatus according to claim 12, further comprising:
a control circuit controlling processing on a substrate,
wherein the control circuit controls loading of the substrate into the chamber, supply of the at least one gas into the chamber, formation of a semiconductor film on the substrate by supply of the first source gas and the second source gas into the chamber, and unloading of the substrate out of the chamber.

14. The semiconductor manufacturing apparatus according to claim 12,
wherein a plasma generator is provided in the first supply pipe.

15. A semiconductor manufacturing apparatus, comprising:
a first supply pipe supplying at least one gas selected from a group consisting of a first gas containing silicon (Si) and a second gas containing oxygen (O);
a second supply pipe supplying a first source gas containing indium (In);
a third supply pipe supplying a second source gas containing oxygen (O);
a first chamber connected with the first supply pipe;
a second chamber connected with the second supply pipe and the third supply pipe; and
a transfer path connecting the first chamber and the second chamber to each other so that an inside of the transfer path is maintainable at a pressure less than atmospheric pressure.

16. The semiconductor manufacturing apparatus according to claim 15, further comprising:
a control circuit controlling processing on a substrate,
wherein the control circuit controls loading of the substrate into the first chamber, supply of the at least one gas into the first chamber, unloading of the substrate out of the first chamber, transfer of the substrate in the transfer path maintained at a pressure less than atmospheric pressure, loading of the substrate into the second chamber, formation of a semiconductor film on the substrate by supply of the first source gas and the second source gas into the second chamber, and unloading of the substrate out of the second chamber.

17. The semiconductor manufacturing apparatus 10 according to claim 15,
wherein a plasma generator is provided in the first supply pipe.
